(19) United States
(12) Patent Application Publication
(10) Pub. No.: US 2010/0270594 A1
(43) Pub. Date: Oct. 28, 2010

(54) IMAGE SENSOR

(75) Inventors: Ryu Shimizu, Mizuho-shi (JP); Mamoru Arimoto, Ogaki-shi (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi (JP)

(21) Appl. No.: 12/723,155

(22) Filed: Mar. 12, 2010

(30) Foreign Application Priority Data
Apr. 28, 2009 (JP) 2009-109018

(51) Int. Cl. H01L 27/148; H01L 27/146

(52) U.S. Cl. 257/225; 257/290; 257/E27.133; 257/E27.15

(57) ABSTRACT

An image sensor according to the present invention includes a second conductivity type first impurity region provided on a surface of a first conductivity type semiconductor substrate for constituting a transfer channel for signal charges, a charge increasing portion provided on the first impurity region for increasing the amount of signal charges by impact ionization, an increasing electrode provided on the side of the surface of the semiconductor substrate for applying a voltage to the charge increasing portion, and a second conductivity type second impurity region opposed to the first impurity region through a prescribed region of the semiconductor substrate and suppliable with charges.

### CROSS-REFERENCE TO RELATED APPLICATION

The priority application number JP2009-109018, Image Sensor, Apr. 28, 2009, Ryu Shimizu, Mamoru Arimoto, upon which this patent application is based is hereby incorporated by reference.

### BACKGROUND OF THE INVENTION

1. Field of the Invention

The present invention relates to an image sensor, and more specifically, it relates to an image sensor including a charge increasing portion for increasing the amount of signal charges by impact ionization.

2. Description of the Background Art

An image sensor including a charge increasing portion for increasing the amount of signal charges by impact ionization is known in general.

For example, known is an image sensor (CCD image sensor) including a charge increasing portion (high-field region in a channel) for increasing (multiplying) the amount of signal charges by impact ionization and an electrode for applying a high voltage for increasing the amount of charges to the charge increasing portion. In such a CCD image sensor, electrons collected in a photoelectric conversion portion (photo site) are transferred to the charge increasing portion, which in turn increases the amount thereof. Thus, sensitivity of the CCD image sensor can be improved.

Also known is a CMOS image sensor (image sensor) including a charge increasing portion for increasing the amount of signal charges by impact ionization and an increasing electrode for applying a high voltage for increasing the amount of charges to the charge increasing portion, for example. Also in such a CMOS image sensor, electrons collected in a photoelectric conversion portion are transferred to the charge increasing portion similarly to the aforementioned CCD image sensor, and the amount of the electrons is increased in a high-field region formed by the high voltage applied to the charge increasing portion.

However, when the charge increasing portion increases the amount of electrons by impact ionization in each of the aforementioned image sensors, for example, a large number of holes are formed in a channel region along with the increase in the amount of the electrons. Therefore, the large number of holes formed along with the increase in the amount of the electrons penetrate into regions other than the channel in the CMOS image sensor, while the holes penetrate in regions other than pixels to cause crosstalk in the CCD image sensor. In each of the CMOS image sensor and the CCD image sensor, further, the holes recombine with electrons formed by impact ionization, to disadvantageously reduce the amount of the electrons (reduce the sensitivity).

### SUMMARY OF THE INVENTION

An image sensor according to a first aspect of the present invention includes a second conductivity type first impurity region provided on a surface of a first conductivity type semiconductor substrate for constituting a transfer channel for signal charges, a charge increasing portion provided on the first impurity region for increasing the amount of signal charges by impact ionization, an increasing electrode provided on the side of the surface of the semiconductor substrate for applying a voltage to the charge increasing portion, and a second conductivity type second impurity region opposed to the first impurity region through a prescribed region of the semiconductor substrate and suppliable with charges.

A CMOS image sensor according to a second aspect of the present invention includes a second conductivity type first impurity region provided on a surface of a first conductivity type semiconductor substrate for constituting a transfer channel for signal charges, a charge increasing portion provided on the first impurity region for increasing the amount of signal charges by impact ionization, an increasing electrode provided on the side of the surface of the semiconductor substrate for applying a voltage to the charge increasing portion, and a second conductivity type second impurity region opposed to the first impurity region through a prescribed region of the semiconductor substrate and suppliable with charges, while the charge increasing portion is provided every pixel.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing the overall structure of a CMOS image sensor according to a first embodiment of the present invention;

FIG. 2 is a plan view of a surface side of a silicon substrate constituting each pixel of the CMOS image sensor according to the first embodiment of the present invention;

FIG. 3 is a plan view of a rear surface side of the silicon substrate constituting each pixel of the CMOS image sensor according to the first embodiment of the present invention;

FIG. 4 is a sectional view of the pixel of the CMOS image sensor according to the first embodiment of the present invention, taken along the line 200-200 in FIG. 3;

FIG. 5 is a circuit diagram showing the circuit structure of the CMOS image sensor according to the first embodiment of the present invention;

FIG. 6 is a potential diagram for illustrating an electron multiplying operation of the CMOS image sensor according to the first embodiment of the present invention;

FIG. 7 is a diagram for illustrating annihilation of holes in the CMOS image sensor according to the first embodiment of the present invention;

FIGS. 8 to 13 are sectional views for illustrating a manufacturing process for the CMOS image sensor according to the first embodiment of the present invention;

FIG. 14 is a plan view of a silicon substrate constituting each pixel of a CMOS image sensor according to a second embodiment of the present invention;

FIG. 15 is a sectional view taken along the line 300-300 in FIG. 14; and

FIG. 16 is a sectional view and a potential diagram of each pixel of a CMOS image sensor according to a third embodiment of the present invention.

### DESCRIPTION OF THE PREFERRED EMBODIMENTS

Embodiments of the present invention are now described with reference to the drawings.

### First Embodiment

A first embodiment of the present invention is applied to an active CMOS image sensor 100, which is an exemplary image sensor.

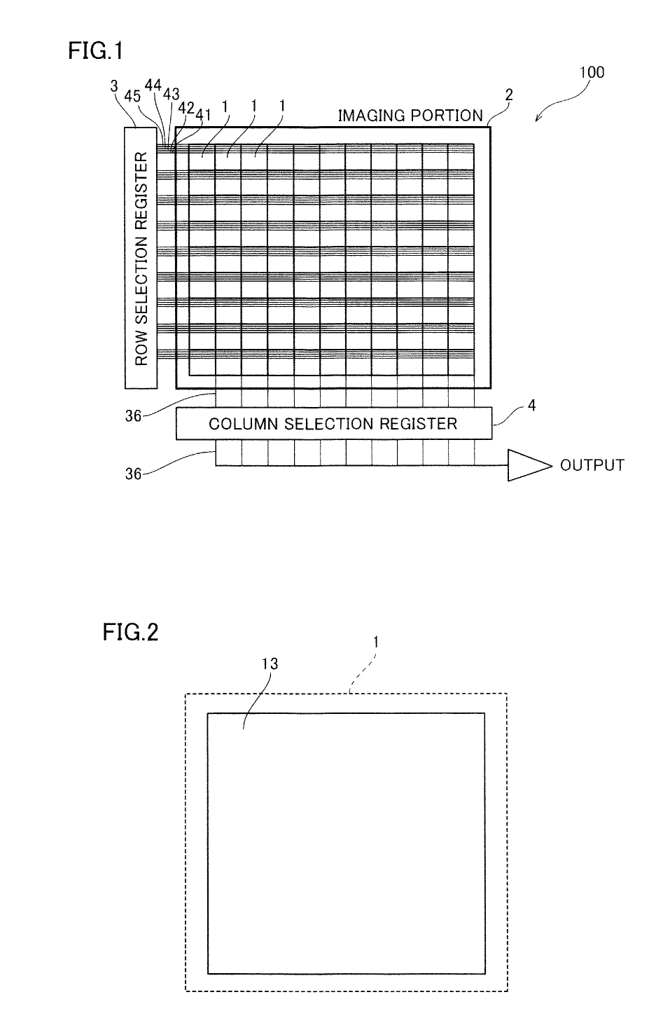

The CMOS image sensor 100 according to the first embodiment includes an imaging portion 2 including a plurality of pixels 1 arranged in the form of a matrix (in rows and columns), a row selection register 3 and a column selection register 4, as shown in FIG. 1.

In the sectional structure of each pixel 1 of the CMOS image sensor 100, an element isolation region 12 for isolating the pixel 1 etc. is formed on a p-type silicon substrate 11, as shown in FIG. 4. The silicon substrate 11 is an example of the “semiconductor substrate” in the present invention.

According to the first embodiment, a photodiode portion (PD portion) 13 consisting of an n-type impurity region is formed on a surface of the silicon substrate 11 along arrow Z1. The PD portion 13 is formed to substantially cover the overall surface of the pixel 1 in plan view, as shown in FIG. 2. The PD portion 13 is opposed to a buried layer 14 described later through a region 11a of the silicon substrate 11, and superposed to entirely cover the buried layer 14 (an electron multiplying portion 14a) in plan view. The PD portion 13 has a function of forming electrons by photoelectric conversion in response to the quantity of light incident upon the same along arrow Z1 and storing (being filled with) the formed electrons. The PD portion 13 is an example of the “second impurity region” or the “photoelectric conversion portion” in the present invention.

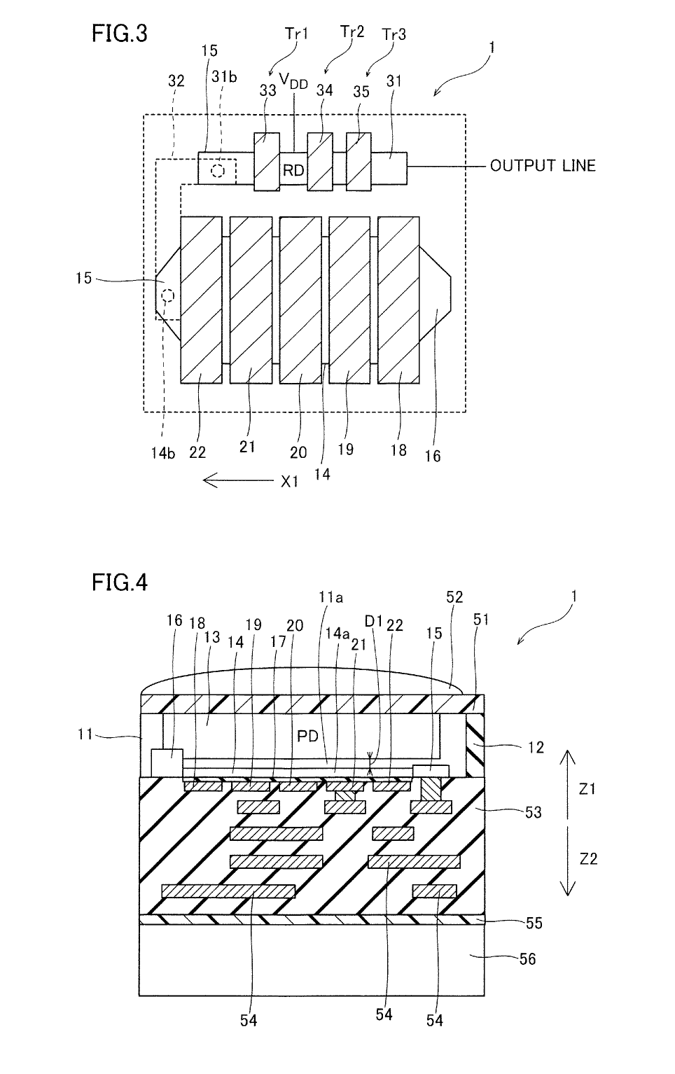

The buried layer 14 consisting of an n-type impurity region constituting a transfer channel for electrons is formed on a surface of the silicon substrate 11 along arrow Z2, while a floating diffusion region (FD region) 15 consisting of an n-type impurity region is formed to be adjacent to the buried layer 14. The FD region 15 has a function of holding signal charges resulting from transferred electrons and converting the signal charges to a voltage in association with a separately connected source follower circuit (constituted of a reset gate transistor Tr1, an amplifier transistor Tr2 and a pixel selection transistor Tr3 shown in FIG. 3 as described later). The PD portion 13 and the buried layer 14 are connected with each other by a connecting portion 16 consisting of an n-type impurity region. The connecting portion 16 may simply be provided on a region other than that opposed to a multiplier gate electrode 21 described later, and is provided on peripheral edges of the PD portion 13 and the buried layer 14 in the first embodiment. The buried layer 14 is an example of the “first impurity region” in the present invention.

The interval (thickness of the region 11a of the silicon substrate 11) D1 between the PD portion 13 and the buried layer 14 is not more than about 2 μm to about 3 μm. The region 11a is an example of the “prescribed region” in the present invention.

A gate insulating film 17 consisting of a silicon oxide film is formed on a surface of the buried layer 14 along arrow Z2. On a surface of the gate insulating film 17 along arrow Z2, a transfer gate electrode 18, a storage gate electrode 19, another transfer gate electrode 20, the multiplier gate electrode 21 and a read gate electrode 22 are formed in this order from the side of the connecting portion 16 toward the side of the FD region 15. The electron multiplying portion 14a for multiplying electrons by impact ionization is provided in a portion of the buried layer 14 located under the multiplier gate electrode 21 (along arrow Z1). The multiplier gate electrode 21 is an example of the “increasing electrode” in the present invention. The electron multiplying portion 14a is an example of the “charge increasing portion” in the present invention.

As shown in FIG. 3, a buried layer 31 consisting of an n-type impurity region is provided on the back surface (surface along arrow Z2) of the silicon substrate 11, separately from the buried layer 14 provided with the electron multiplying portion 14a. A region (FD region 15) of the buried layer 14 around an end portion along arrow X1 and a region (FD region 15) of the buried layer 31 around an end portion along arrow X1 are electrically connected with each other through a wiring layer 32 and contact portions 14b and 31b. The wiring layer 32 is formed on a layer different from the transfer gate electrode 18 etc. formed on the surface of the gate insulating film 17. Gate electrodes 33, 34 and 35 of the reset gate transistor Tr1, the amplifier transistor Tr2 and the pixel selection transistor Tr3 are provided on the surface of the buried layer 31 (unshown gate insulating film). A power supply potential (V_{DD}) is electrically connected to a portion (reset drain: RD) of the buried layer 31 corresponding to the space between the gate electrodes 33 and 34.

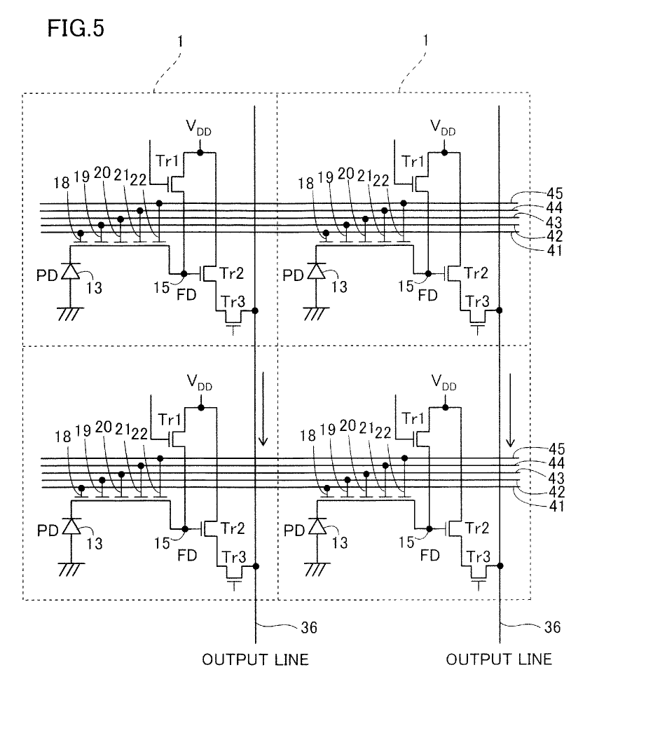

As shown in FIGS. 3 and 5, the FD region 15 is connected to either the source or the drain of the reset gate transistor Tr1 and the gate of the amplifier transistor Tr2. Either the drain or the source of the reset transistor Tr1 and either the source or the drain of the amplifier transistor Tr2 are connected to the power supply potential V_{DD}. Either the drain or the source of the amplifier transistor Tr2 is connected to either the source or the drain of the pixel selection transistor Tr3. Either the drain or the source of the pixel selection transistor Tr3 is connected to an output line 36.

As shown in FIG. 5, wiring layers 41, 42, 43, 44 and 45 supplying clock signals for voltage control are electrically connected to the transfer gate electrode 18, the storage gate electrode 19, the transfer gate electrode 20, the multiplier gate electrode 21 and the read gate electrode 22 respectively. The wiring layers 41 to 45 are formed every row of the pixels 1 arranged in the form of a matrix, and electrically connected to transfer gate electrodes 18, storage gate electrodes 19, transfer gate electrodes 20, multiplier gate electrodes 21 and read gate electrodes 22 of a plurality of pixels 1 forming each row respectively.

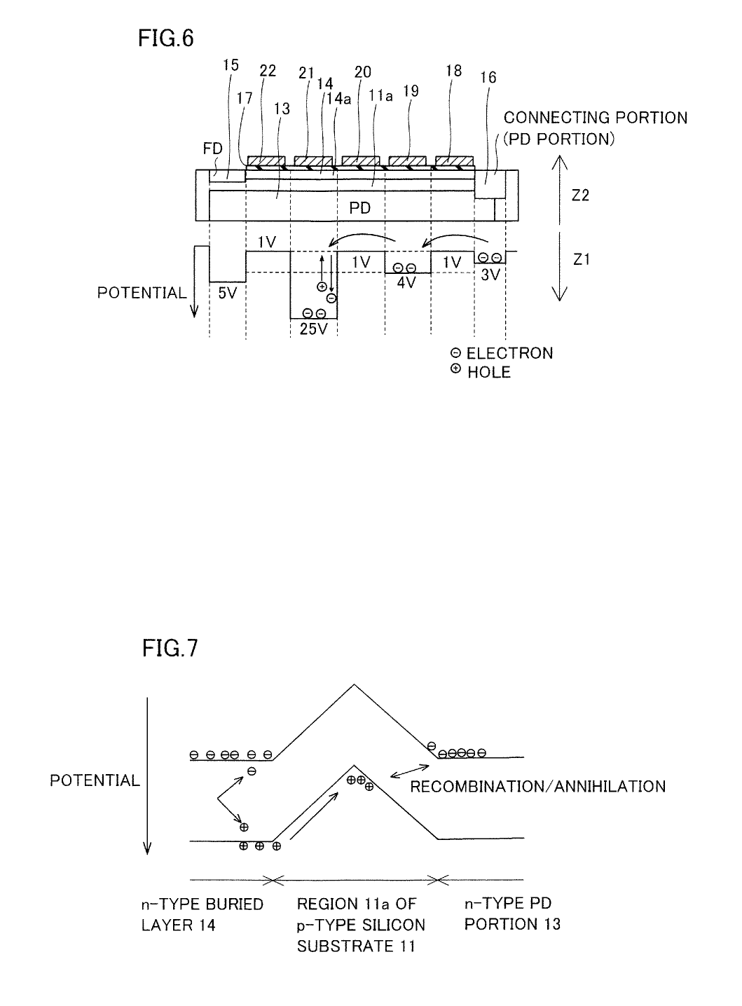

When ON-state (OFF-state) clock signals are supplied to the transfer gate electrode 18, the storage gate electrode 19, the transfer gate electrode 20 and the read gate electrode 22 of each pixel 1 through the wiring layers 41, 42, 43 and 45 respectively, portions of the buried layer 14 located under the transfer gate electrode 18, the storage gate electrode 19, the transfer gate electrode 20 and the read gate electrode 22 are controlled to reach potentials of about 4 V (about 1 V), for example, as shown in FIG. 6. When an ON-state (OFF-state) clock signal is supplied to the multiplier gate electrode 21 from the wiring layer 21, a portion of the buried layer 14 located under the multiplier gate electrode 21 is controlled to reach a potential of about 25 V (about 1 V), for example. The PD portion 13 is controlled to reach a potential of about 3 V, for example, while the FD region 15 is controlled to reach a potential of about 5 V, for example.

As shown in FIG. 4, a color filter 51 is formed on the surface of the PD portion 13, while a microlens 52 is formed on the surface of the color filter 51. Multilayered wiring layers 54 are formed on the surface of the silicon substrate 11 along arrow Z2 through an insulating layer 53. A support substrate 56 is provided on a surface of the insulating layer 53 along arrow Z2 through a bonding layer 55.

An electron multiplying operation of the CMOS image sensor 100 according to the first embodiment of the present invention is now described with reference to FIG. 6.

When light is incident upon the PD portion 13 along arrow Z1, the PD portion 13 forms electrons by photoelectric conversion. The electrons formed by the PD portion 13 (about 3 V) are temporarily stored in the portion (about 4 V) of the buried layer 14 located under the ON-state storage gate electrode 19 through the connecting layer 16 and the portion (about 4 V) of the buried layer 14 located under the ON-state transfer gate electrode 18. Then, the transfer gate electrode 20 is brought into an ON-state and the storage gate electrode 19 is brought into an OFF-state, whereby the electrons stored in the portion located under the storage gate electrode 19 are transferred to the portion (about 25 V) of the buried layer 14 located under the ON-state multiplier gate electrode 21 through the portion (about 4 V) of the buried layer 14 located under the transfer gate electrode 20. At this time, the portion (electron multiplying portion 14a) of the buried layer 14 located under the boundary between the transfer gate electrode 20 and the multiplier gate electrode 21 multiplies the electrons by impact ionization.

Then, the multiplier gate electrode 21 is brought into an OFF-state while the transfer gate electrode 20 is kept in the ON-state, whereby the electrons multiplied in the electron multiplying portion 14a are stored in the portion (about 4 V) of the buried layer 14 located under the ON-state storage gate electrode 19 again through the portion (about 4 V) of the buried layer 14 located under the transfer gate electrode 20. Thus, the CMOS image sensor 100 multiplies the electrons by repeating the operation of transferring the electrons from the portion of the buried layer 14 located under the storage gate electrode 19 to the portion (about 25 V) of the buried layer 14 located under the ON-state multiplier gate electrode 21 thereby multiplying the same and the operation of transferring the electrons from the portion of the buried layer 14 located under the multiplier gate electrode 21 to the portion of the buried layer 14 located under the storage gate electrode 19 by a prescribed number of times.

As shown in FIG. 6, the electron multiplying portion 14a also forms holes along with the electrons when multiplying the electrons by impact ionization. As shown in FIG. 7, the holes penetrate into the PD portion 13 through the region 11a (p-type) of the silicon substrate 11 located between the buried layer 14 and the PD portion 13. The PD portion 13 forms a large number of electrons by photoelectric conversion, and the holes penetrating into the PD portion 13 recombine with the electrons formed by photoelectric conversion, whereby the electrons and the holes annihilate. Thus, the electrons are multiplied by impact ionization, while multiplication of holes formed along with the multiplication of the electrons is suppressed.

After the electrons are multiplied by a desired number of times, the multiplier gate electrode 21 is brought into an OFF-state and the read gate electrode 22 is kept in an ON-state, whereby the electrons stored in the portion of the buried layer 14 located under the multiplier gate electrode 21 are transferred to the FD region 15 through the portion (about 4 V) of the buried layer 14 located under the ON-state read gate electrode 22. The multiplier transistor Tr2 multiplies a signal voltage resulting from the electrons stored in the FD region 15. Further, a prescribed pixel 1 is selected and the pixel selection transistor Tr3 is brought into an ON-state, whereby the signal voltage multiplied by the multiplier transistor Tr2 is output to the output line 36.

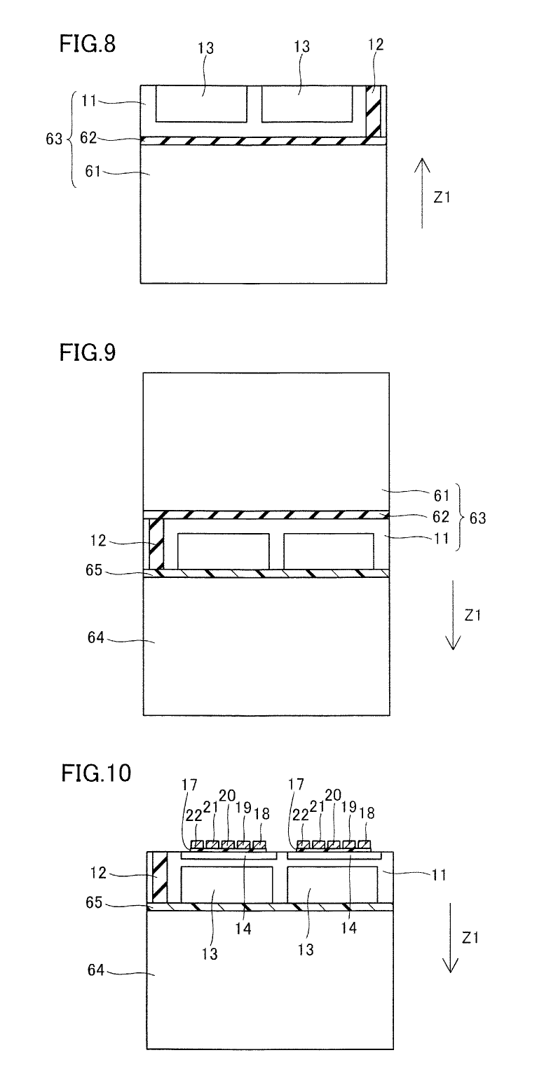

A manufacturing process for the CMOS image sensor 100 according to the first embodiment of the present invention is now described with reference to FIGS. 4 and 8 to 13. Each of FIGS. 8 to 13 shows two pixels 1.

As shown in FIG. 8, the element isolation region 12 consisting of an insulating film such as a silicon oxide film, for example, is formed on an SOI substrate 63 having a silicon oxide film 62 inserted between a silicon substrate 61 and a surface silicon layer (silicon substrate 11), to be connected to the silicon oxide film 62. Then, the PD portion 13 is formed every pixel 1 by implanting an n-type impurity into the surface of the SOI substrate 63.

Then, a support substrate 64 is bonded to the surface of the SOI substrate 63 provided with each PD portion 13 through a bonding layer 65, and the SOI substrate 63 and the support substrate 64 are thereafter inverted, as shown in FIG. 9.

Then, the silicon substrate 61 and the silicon oxide film 62 are removed by back grinding (BG), chemical mechanical polishing (CMP) or wet etching, as shown in FIG. 10. Then, the buried layer 14 is formed every pixel 1 by implanting an n-type impurity into the surface of the silicon substrate 11. Then, the gate insulating film 17 is formed by forming a film consisting of a silicon oxide film on the surface of the silicon substrate 11 and thereafter patterning the same into a prescribed size. Further, the transfer gate electrode 18, the storage gate electrode 19, the transfer gate electrode 20, the multiplier gate electrode 21 and the read gate electrode 22 are formed on the surface of the gate insulating film 17.

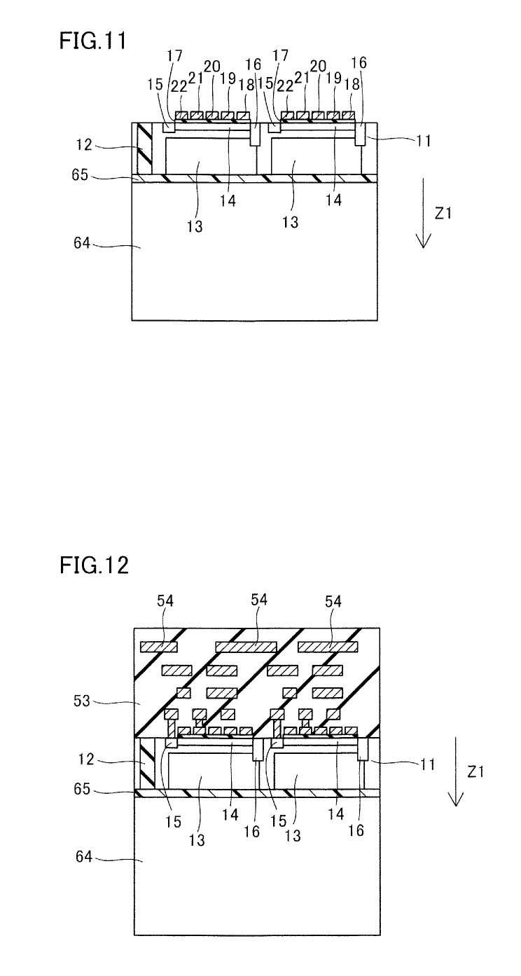

Then, the connecting portion 16 is formed by forming a resist film (not shown) on a prescribed region of the surface of the silicon substrate 11 and thereafter implanting and diffusing an n-type impurity up to a depth reaching the PD portion 13, as shown in FIG. 11. Thus, the PD portion 13 and the buried layer 14 are connected with each other. Similarly, the FD region 15 is formed by forming a resist film (not shown) on another prescribed region of the surface of the silicon substrate 11 and thereafter implanting an n-type impurity.

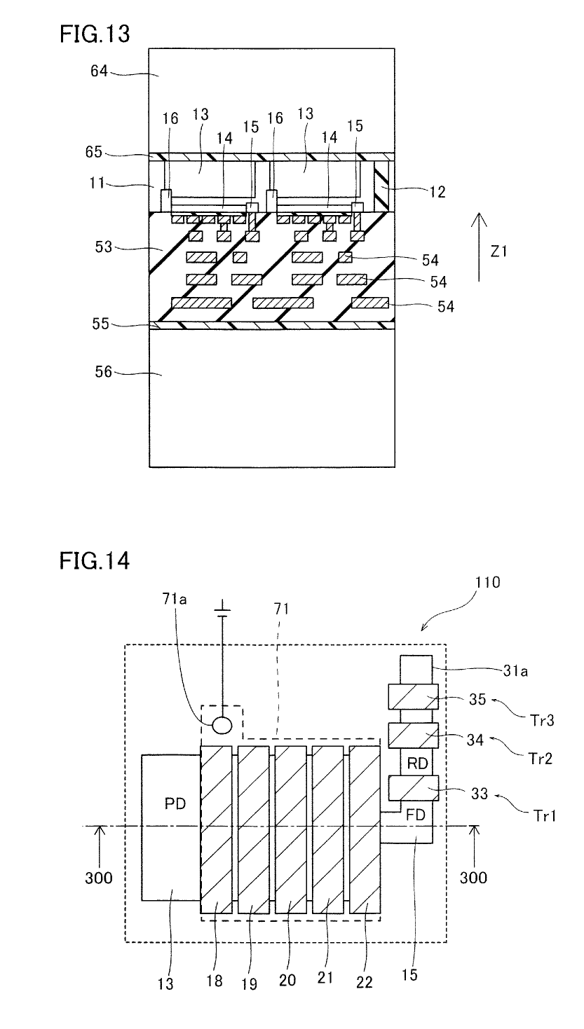

Then, the multilayered wiring layers 54 are formed on the surface of the silicon substrate 11 through the insulating layer 53, as shown in FIG. 12. Then, the support substrate 56 is bonded to the surface of the insulating layer 53 through the bonding layer 55, and the support substrate 64, the silicon substrate 11 and the support substrate 56 are inverted, as shown in FIG. 13. Thereafter the support substrate 64 and the bonding layer 65 are removed by back grinding (BG), chemical mechanical polishing (CMP) or wet etching, and the color filter 51 and the microlens 52 are thereafter formed on the surface of the PD portion 13 as shown in FIG. 4, whereby the CMOS image sensor 100 is completed.

The CMOS image sensor 100 according to the first embodiment of the present invention can attain the following effects:

(1) The CMOS image sensor 100 includes the PD portion 13 superposed to be opposed to the buried layer 14 (electron multiplying portion 14a) through the region 11a of the p-type silicon substrate 11, whereby holes formed when the electron multiplying portion 14a multiplies electrons penetrate into the PD portion 13 through the region 11a of the silicon substrate 11. The penetrating holes annihilate by recombining with electrons formed by photoelectric conversion and filling the PD portion 13. Thus, holes formed when electrons are multiplied can be inhibited from penetrating into regions other than the buried layer 14 and causing crosstalk or recombining with electrons formed by impact ionization and reducing the amount of multiplied electrons (reducing sensitivity).

(2) The n-type impurity region opposed to the buried layer 14 constitutes the PD portion 13, whereby electrons for recombining with holes can be easily formed.

(3) The PD portion 13 is formed on the surface of the silicon substrate 11 opposite to the side provided with the buried layer 14 so that external light can be easily incident upon the PD portion 13, whereby electrons for recombining with holes can be easily formed.

(4) The PD portion 13 is superposed to cover the buried layer 14 (electron multiplying portion 14a) in plan view, whereby holes can be more reliably inhibited from flying out toward regions other than the buried layer 14, dissimilarly to a case where the PD portion 13 partially covers the buried layer 14 (electron multiplying portion 14a).

### Second Embodiment

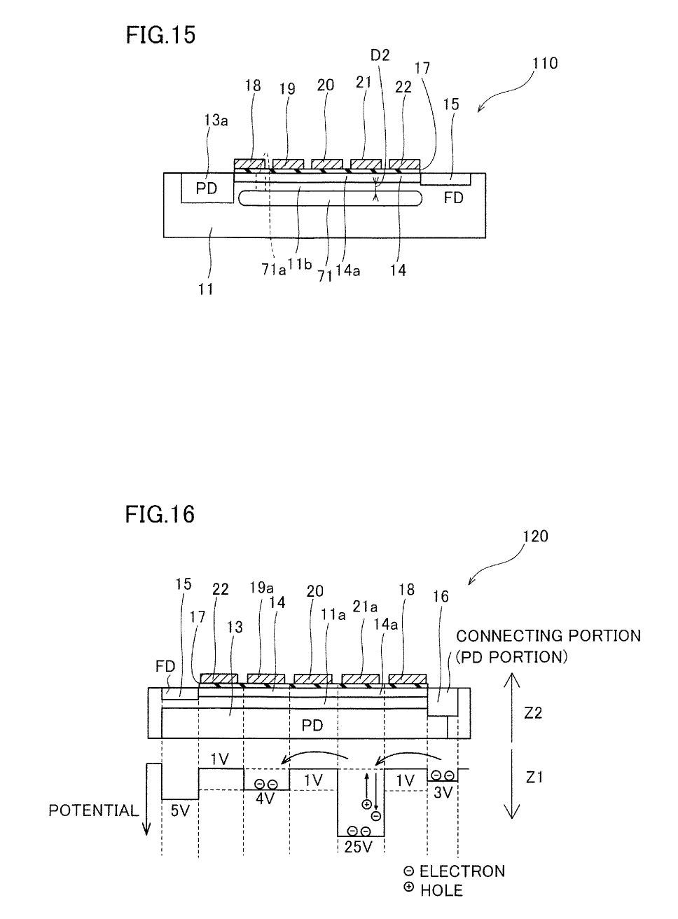

A CMOS image sensor 110 according to a second embodiment of the present invention is now described with reference to FIGS. 14 and 15. In the CMOS image sensor 110 according to the second embodiment of the present invention, an n-type impurity region 71 is provided in a silicon substrate 11, dissimilarly to the aforementioned first embodiment.

In the CMOS image sensor 110 according to the second embodiment of the present invention, a PD portion 13a is provided on the surface of the silicon substrate 11 to be adjacent to a buried layer 14, as shown in FIG. 15. A gate insulating film 17 consisting of a silicon oxide film is formed on the surface of the buried layer 14. A transfer gate electrode 18, a storage gate electrode 19, another transfer gate electrode 20, a multiplier gate electrode 21 and a read gate electrode 22 are formed on the surface of the gate insulating film 17 in this order from the side of the PD portion 13a toward the side of an FD region 15. As shown in FIG. 14, gate electrodes 33, 34 and 35 of a reset gate transistor Tr1, an amplifier transistor Tr2 and a pixel selection transistor Tr3 are provided on the surface of a buried layer 31a (unshown gate insulating film).

As shown in FIG. 15, the n-type impurity region 71 is provided in the silicon substrate 11, to be opposed to the buried layer 14. The interval (thickness of a region 11b) D2 between the buried layer 14 and the impurity region 71 is not more than about 2 μm to about 3 μm. As shown in FIG. 14, the impurity region 71 is partially drawn out on the surface of the silicon substrate 11, and has a drawn portion 71a on the surface of the silicon substrate 11. A bias portion (not shown) bringing a negative potential, for example, is connected to the drawn portion 71a, thereby supplying electrons to the impurity region 71. The impurity region 71 is superposed to entirely cover the buried layer 14 in plan view. The PD portion 13a is an example of the “third impurity region” or the “photoelectric conversion portion” in the present invention. The impurity region 71 is an example of the “second impurity region” in the present invention. The region 11b is an example of the “prescribed region” in the present invention.

The remaining structure of the second embodiment is similar to that of the aforementioned first embodiment.

The CMOS image sensor 110 according to the second embodiment of the present invention can attain the following effects:

(5) The impurity region 71 is provided in the silicon substrate 11 to be opposed to the buried layer 14, whereby holes formed when an electron multiplying portion 14a multiplies electrons penetrate into the impurity region 71 through the region 11b of the silicon substrate 11. The penetrating holes annihilate by recombining with electrons supplied from the bias portion bringing a negative potential to fill the impurity region 71. Thus, holes formed when electrons are multiplied can be inhibited from penetrating into regions other than the buried layer 14 and causing crosstalk or recombining with electrons formed by impact ionization and reducing the amount of multiplied electrons (reducing sensitivity).

(6) The drawn portion 71a of the impurity region 71 is provided on the surface of the silicon substrate 11, whereby the bias portion bringing a negative potential can be easily connected to the drawn portion 71a of the impurity region 71. Thus, electrons for combining with holes can be inhibited from disappearance, dissimilarly to a case where the impurity region 71 is in a floating state.

### Third Embodiment

A CMOS image sensor 120 according to a third embodiment of the present invention is now described with reference to FIG. 16. In the CMOS image sensor 120 according to the third embodiment of the present invention, a multiplier gate electrode 21a is provided to be adjacent to a transfer gate electrode 18 adjacent to a connecting portion 16, dissimilarly to the aforementioned first embodiment.

In the CMOS image sensor 120 according to the third embodiment, the transfer gate electrode 18, the multiplier gate electrode 21a, another transfer gate electrode 20, a storage gate electrode 19a and a read gate electrode 22 are formed on a surface of a gate insulating film 17 along arrow Z2 in this order from the side of the connecting portion 16 toward the side of an FD region 15, as shown in FIG. 16. An electron multiplying portion 14a for multiplying electrons by impact ionization is provided in a portion of a buried layer 14 located under the multiplier gate electrode 21a (along arrow Z1). The multiplier gate electrode 21a is an example of the “increasing electrode” in the present invention.

The remaining structure of the third embodiment is similar to that of the aforementioned first embodiment.

An electron multiplying operation of the CMOS image sensor 120 according to the third embodiment of the present invention is now described with reference to FIG. 16.

When light is incident upon a PD portion 13 along arrow Z1, the PD portion 13 forms electrons by photoelectric conversion. The electrons formed by the PD portion 13 (about 3 V) are temporarily stored in the portion (about 25 V) of the buried layer 14 located under the ON-state multiplier gate electrode 21a through the connecting layer 16 and a portion (about 4 V) of the buried layer 14 located under the ON-state transfer gate electrode 18. At this time, the portion (electron multiplying portion 14a) of the buried layer 14 located under the boundary between the transfer gate electrode 18 and the multiplier gate electrode 21 multiplies the electrons by impact ionization.

The multiplier gate electrode 21a is brought into an OFF-state and the transfer gate electrode 20 is brought into an ON-state, whereby the electrons multiplied in the electron multiplier portion 14a are stored in a portion (about 4 V) of the buried layer 14 located under the ON-state storage gate electrode 19a through a portion (about 4 V) of the buried layer 14 located under the transfer gate electrode 20.

Holes formed along with the electrons multiplied by impact ionization penetrate into the PD portion 13 and recombine with the electrons formed by the PD portion 13 by photoelectric conversion similarly to the aforementioned first embodiment, whereby the electrons and the holes annihilate. Thus, the electrons are multiplied by impact ionization, while multiplication of the holes formed along with the multiplication of the electrons is suppressed.

Then, the transfer gate electrode 20 is kept in the ON-state while the storage gate electrode 19a is brought into an OFF-state, whereby the electrons stored in the portion located under the storage gate electrode 19a are transferred to the portion (about 25 V) of the buried layer 14 located under the ON-state multiplier gate electrode 21a. At this time, the portion (electron multiplying portion 14a) of the buried layer 14 located under the boundary between the transfer gate electrode 20 and the multiplier gate electrode 21a multiplies the electrons by impact ionization again. Thus, the CMOS image sensor 120 multiplies electrons by repeating the operation of transferring the electrons from the portion of the buried layer 14 located under the storage gate electrode 19a to the portion (about 25 V) of the buried layer 14 located under the ON-state multiplier gate electrode 21a thereby multiplying the same and the operation of transferring the electrons from the portion of the buried layer 14 located under the multiplier gate electrode 21a to the portion of the buried layer 14 located under the storage gate electrode 19a by a prescribed number of times.

After the electrons are multiplied by the desired number of times, the storage gate electrode 19a is brought into an OFF-state and the read gate electrode 22 is brought into an ON-state, whereby the electrons stored in the portion of the buried layer 14 located under the storage gate electrode 19a are transferred to the FD region 15 through a portion (about 4 V) of the buried layer 14 located under the ON-state read gate electrode 22. The amplifier transistor Tr2 amplifies a signal voltage resulting from the electrons stored in the FD region 15. A prescribed pixel 1 is selected and the pixel selection transistor Tr3 is brought into an ON-state, whereby the signal voltage multiplied by the multiplier transistor Tr2 is output to an output line 36.

The CMOS image sensor 120 according to the third embodiment of the present invention can attain effects similar to those of the first embodiment.

Although the present invention has been described and illustrated in detail, it is clearly understood that the same is by way of illustration and example only and is not to be taken by way of limitation, the spirit and scope of the present invention being limited only by the terms of the appended claims.

While the electrons are supplied to the n-type PD portion 13 (first or third embodiment) or the n-type impurity region 71 (second embodiment) in each of the aforementioned first to third embodiments, the present invention is not restricted to this. For example, the conductivity types of the p- and n-type regions may be reversed so that holes are supplied to a p-type PD portion or a p-type impurity region in each of the first to third embodiments.

While the n-type PD portion 13 (first or third embodiment) or the n-type impurity region 71 (second embodiment) is superposed to entirely cover the buried layer 14 in plan view in each of the aforementioned first to third embodiments, the present invention is not restricted to this. For example, the PD portion 13 or the n-type impurity region 71 may alternatively be formed to cover at least the electron multiplying portion 14a of the buried layer 14 in plan view.

While the PD portion 13 and the buried layer 14 are connected with each other by the connecting portion 16 consisting of the n-type impurity region in each of the aforementioned first and third embodiments, the present invention is not restricted to this, but the PD portion 13 and the buried layer 14 may alternatively be connected with each other by a metal layer.

While the regions of the FD region 15 closer to the buried layers 14 and 31 respectively are electrically connected with each other by the wiring layer 32 in each of the aforementioned first and third embodiments, the present invention is not restricted to this, but the buried layers 14 and 31 may alternatively be connected with each other by an impurity region.

While the present invention is applied to the CMOS image sensor as an image sensor in each of the aforementioned first to third embodiments, the present invention is not restricted to this, but may alternatively be applied to a CCD image sensor as an image sensor.

While five gate electrodes in total, i.e., the two transfer gate electrodes, the storage gate electrode, the multiplier gate electrode and the read gate electrode are employed in each of the aforementioned first to third embodiments, the present invention is not restricted to this, but the image sensor may alternatively be constituted of three or four gate electrodes.

What is claimed is:

1. An image sensor comprising:
a second conductivity type first impurity region provided on a surface of a first conductivity type semiconductor substrate for constituting a transfer channel for signal charges;
a charge increasing portion provided on said first impurity region for increasing the amount of signal charges by impact ionization;
an increasing electrode provided on the side of said surface of said semiconductor substrate for applying a voltage to said charge increasing portion; and
a second conductivity type second impurity region opposed to said first impurity region through a prescribed region of said semiconductor substrate and suppliable with charges.

2. The image sensor according to claim 1, wherein
said second impurity region is provided to overlap with at least a region of said first impurity region functioning as said charge increasing portion in plan view.

3. The image sensor according to claim 1, wherein
said second impurity region is formed on a surface of said semiconductor substrate opposite to the side provided with said first impurity region, and constitutes a photoelectric conversion portion forming signal charges by incident light.

4. The image sensor according to claim 3, further comprising a connecting portion electrically connecting said second impurity region constituting said photoelectric conversion portion and said first impurity region with each other.

5. The image sensor according to claim 4, wherein
said connecting portion is provided on a region other than a region where said second impurity region constituting said photoelectric conversion portion and said first impurity region are opposed to each other in plan view.

6. The image sensor according to claim 5, wherein
said connecting portion is provided on peripheral edge portions of said second impurity region constituting said photoelectric conversion portion and said first impurity region in plan view.

7. The image sensor according to claim 3, wherein
said second impurity region constituting said photoelectric conversion portion is provided to overlap substantially with the overall region of said first impurity region in plan view.

8. The image sensor according to claim 3, wherein
said second impurity region constituting said photoelectric conversion portion is provided to substantially cover the overall surface of a pixel in plan view.

9. The image sensor according to claim 3, wherein
said first impurity region constituting said transfer channel and said second impurity region constituting said photoelectric conversion portion are of n-types.

10. The image sensor according to claim 1, further comprising a second conductivity type third impurity region provided on said surface of said semiconductor substrate to be adjacent to said first impurity region for constituting a photoelectric conversion portion forming signal charges by incident light, wherein
said second impurity region is connected to a bias portion bringing a positive or negative potential.

11. The image sensor according to claim 10, wherein
said second impurity region is provided to be embedded in said semiconductor substrate.

12. The image sensor according to claim 11, wherein
said second impurity region includes a portion embedded in said semiconductor substrate and a drawing portion drawing said embedded portion on said surface of said semiconductor substrate, and
said bias portion bringing a positive or negative potential is connected to said drawing portion.

13. The image sensor according to claim 10, wherein
said first impurity region and said second impurity region are of n-types, and
said second impurity region is connected to said bias portion bringing a negative potential.

14. The image sensor according to claim 1, wherein
said prescribed region includes a first conductivity type fourth impurity region, and
said second conductivity type second impurity region is opposed to said second conductivity type first impurity region through said first conductivity type fourth impurity region.

15. The image sensor according to claim 1, further comprising:
a voltage conversion portion provided on the side of said surface of said semiconductor substrate for converting charges increased in amount by said charge increasing portion to a voltage, and
a read electrode provided on the side of said surface of said semiconductor substrate to be adjacent to said voltage conversion portion for reading said charges increased in amount by said charge increasing portion on said voltage conversion portion, wherein
said increasing electrode is provided to be adjacent to a side of said read electrode opposite to said voltage conversion portion.

16. The image sensor according to claim 1, further comprising:
a voltage conversion portion provided on the side of said surface of said semiconductor substrate for converting charges increased in amount by said charge increasing portion to a voltage,
a read electrode provided on the side of said surface of said semiconductor substrate to be adjacent to said voltage conversion portion for reading said charges increased in amount by said charge increasing portion on said voltage conversion portion, and
a transfer electrode provided on a side of said read electrode opposite to said voltage conversion portion, wherein
said increasing electrode is provided to be adjacent to a side of said transfer electrode opposite to said read electrode.

17. A CMOS image sensor comprising:
a second conductivity type first impurity region provided on a surface of a first conductivity type semiconductor substrate for constituting a transfer channel for signal charges;
a charge increasing portion provided on said first impurity region for increasing the amount of signal charges by impact ionization;
an increasing electrode provided on the side of said surface of said semiconductor substrate for applying a voltage to said charge increasing portion; and
a second conductivity type second impurity region opposed to said first impurity region through a prescribed region of said semiconductor substrate and suppliable with charges, wherein
said charge increasing portion is provided every pixel.

18. The CMOS image sensor according to claim 17, wherein
said second impurity region is provided to overlap with at least a region of said first impurity region functioning as said charge increasing portion in plan view.

19. The CMOS image sensor according to claim 17, wherein
said second impurity region is formed on a surface of said semiconductor substrate opposite to the side provided with said first impurity region, and constitutes a photoelectric conversion portion forming signal charges by incident light.

20. The CMOS image sensor according to claim 17, further comprising a second conductivity type third impurity region provided on said surface of said semiconductor substrate to be adjacent to said first impurity region for constituting a photoelectric conversion portion forming signal charges by incident light, wherein
said second impurity region is connected to a bias portion bringing a positive or negative potential.
